(19) United States
(12) Patent Application Publication
(10) Pub. No.: US 2017/0016745 A1
(43) Pub. Date: Jan. 19, 2017

(54) MAGNETIC SENSOR

(71) Applicant: Panasonic Intellectual Property Management Co., Ltd., Osaka-shi (JP)

(72) Inventors: KAZUHIRO ONAKA, Hyogo (JP); NORITAKA ICHINOMIYA, Nara (JP); KIYOTAKA YAMADA, Osaka (JP); SHIGEHIRO YOSHIUCHI, Kyoto (JP)

(21) Appl. No.: 15/121,021

(22) PCT Filed: Mar. 12, 2015
(86) PCT No.: PCT/JP2015/001381

§ 371 Date: Aug. 23, 2016

(30) Foreign Application Priority Data
Mar. 24, 2014 (JP) 2014-060152
Jun. 27, 2014 (JP) 2014-132237
Dec. 10, 2014 (JP) 2014-250070

(51) Int. Cl. G01D 5/16; H01L 43/08

(52) U.S. Cl. CPC G01D 5/16; H01L 43/08

(57) ABSTRACT

A magnetic sensor includes a substrate, a magnetoresistive element group, and a magnet group. The substrate has a first surface and a second surface opposite to the first surface. The magnetoresistive element group includes a first magnetoresistive element and a second magnetoresistive element. The first magnetoresistive element and the second magnetoresistive element are located on the first surface of the substrate. The magnet group includes a first magnet opposing the first magnetoresistive element and a second magnet opposing the second magnetoresistive element.

### TECHNICAL FIELD

The present invention relates to a magnetic sensor including bias magnets.

### BACKGROUND ART

Conventional magnetic sensors are disclosed in, for example, Patent Literature 1 and 2. PTL 1 discloses a structure in which one bias magnet is located right under four magnetoresistive elements. PTL 2 discloses a structure in which one bias magnet is located over magnetoresistive elements.

### CITATION LIST

### Patent Literature

PTL 1: Japanese Unexamined Patent Application Publication No. 2006-208025

PTL 2: Japanese Unexamined Patent Application Publication No. 2013-024674

### SUMMARY OF THE INVENTION

It is an object of the present invention to provide a highly compact, highly accurate magnetic sensor.

The magnetic sensor according to the present invention includes a substrate, a magnetoresistive element group, and a magnet group. The substrate has a first surface and a second surface opposite to the first surface. The magnetoresistive element group includes a first magnetoresistive element and a second magnetoresistive element. The first magnetoresistive element and the second magnetoresistive element are located on the first surface of the substrate. The magnet group includes a first magnet opposing the first magnetoresistive element and a second magnet opposing the second magnetoresistive element.

This structure provides a highly compact, highly accurate magnetic sensor.

### BRIEF DESCRIPTION OF DRAWINGS

FIG. 1 is a schematic diagram of a magnetic sensor according to a first exemplary embodiment.

FIG. 2 is a schematic top view of a substrate including magnetoresistive elements in the magnetic sensor according to the first exemplary embodiment.

FIG. 3A is a schematic diagram in which the magnetic sensor according to the first exemplary embodiment is located beside a magnet-to-be-detected.

FIG. 3B is a schematic diagram in which the magnetic sensor according to the first exemplary embodiment is located above the magnet-to-be-detected.

FIG. 4A is an enlarged view of the first magnetoresistive element shown in FIG. 2.

FIG. 4B is a sectional view of the first magnetoresistive element taken along line 4B-4B of FIG. 4A.

FIG. 5A shows a first example of the bias magnetic field direction of each magnet of a magnet group.

FIG. 5B shows a second example of the bias magnetic field direction of each magnet of the magnet group.

FIG. 6 is a schematic diagram of a magnetic sensor according to a second exemplary embodiment.

FIG. 7A is a schematic top view of a substrate including magnetoresistive elements in the magnetic sensor according to the second exemplary embodiment.

FIG. 7B is an explanatory drawing of the bias magnetic field direction of each magnet of a magnet group in the magnetic sensor according to the second exemplary embodiment.

FIG. 7C is a sectional view taken along line 7C-7C of FIG. 7A.

FIG. 8A is a schematic top view of the substrate including the magnetoresistive elements in a magnetic sensor according to a first modified example of the second exemplary embodiment.

FIG. 8B is an explanatory drawing of the bias magnetic field direction of each magnet of the magnet group in the magnetic sensor according to the first modified example of the second exemplary embodiment.

FIG. 8C is a sectional view taken along line 8C-8C of FIG. 8A.

FIG. 9A is a schematic top view of the substrate including the magnetoresistive elements in the magnetic sensor according to a second modified example of the second exemplary embodiment.

FIG. 9B is an explanatory drawing of the bias magnetic field direction of each magnet of the magnet group in the magnetic sensor according to the second modified example of the second exemplary embodiment.

FIG. 9C is a sectional view taken along line 9C-9C of FIG. 9A.

FIG. 10 is a schematic sectional view of a structure including the magnetic sensor according to the exemplary embodiment.

FIG. 11A is a perspective view of a magnetic sensor according to a third exemplary embodiment of the present invention.

FIG. 11B is a top view of the magnetic sensor shown in FIG. 11A.

FIG. 11C is a perspective view of a first substrate in the magnetic sensor shown in FIG. 11A.

FIG. 11D is a top view of another first substrate in the magnetic sensor according to the third exemplary embodiment of the present invention.

FIG. 12A is a perspective view of a magnetic sensor according to a first modified example of the third exemplary embodiment of the present invention.

FIG. 12B is a top view of the magnetic sensor shown in FIG. 12A.

FIG. 12C is a perspective view of the first substrate and a second substrate in the magnetic sensor shown in FIG. 12A.

FIG. 13A is a perspective view of a magnetic sensor according to a second modified example of the third exemplary embodiment of the present invention.

FIG. 13B is a top view of the magnetic sensor shown in FIG. 13A.

FIG. 13C is a perspective view and a rear view of the first substrate in the magnetic sensor shown in FIG. 13A.

FIG. 13D is a sectional view of the magnetoresistive elements on the first substrate shown in FIG. 13C.

FIG. 13E is a rear view of another first substrate in the magnetic sensor according to the second modified example of the third exemplary embodiment of the present invention.

FIG. 14A is a front view of a wafer used to manufacture the magnetic sensor according to the third exemplary embodiment of the present invention.

FIG. 14B is a sectional view taken along line 14B-14B of FIG. 14A.

FIG. 15A is a drawing illustrating a process of forming the substrate of the magnetic sensor according to the third exemplary embodiment of the present invention.

FIG. 15B is a drawing illustrating another process of forming the substrate of the magnetic sensor according to the third exemplary embodiment of the present invention.

### DESCRIPTION OF EMBODIMENTS

Prior to describing exemplary embodiments of the present invention, problems in conventional magnetic sensors disclosed in PTL 1 and 2 will now be described. In the conventional magnetic sensors, one bias magnet is located to correspond to one or more metal patterns, such as one or more magnetoresistive elements. Such structures cannot be reduced in size or improved in accuracy.

Magnetic sensors according to the exemplary embodiments of the present invention will now be described with reference to drawings. In these drawings, the same components as in the preceding drawings may not be labeled with reference numerals in the subsequent drawings, and a description of these components may be omitted in the subsequent embodiments. In addition, the same components as in the preceding embodiments will be denoted by the same reference numerals in the subsequent embodiments, and a detailed description of these components may be omitted in the subsequent embodiments. Each drawing shows a preferred example, and their structures, shapes, and values are not limited to those shown in these drawings. Furthermore, the elemental technologies described in the exemplary embodiments can be combined as long as no contradiction arises.

### First Exemplary Embodiment

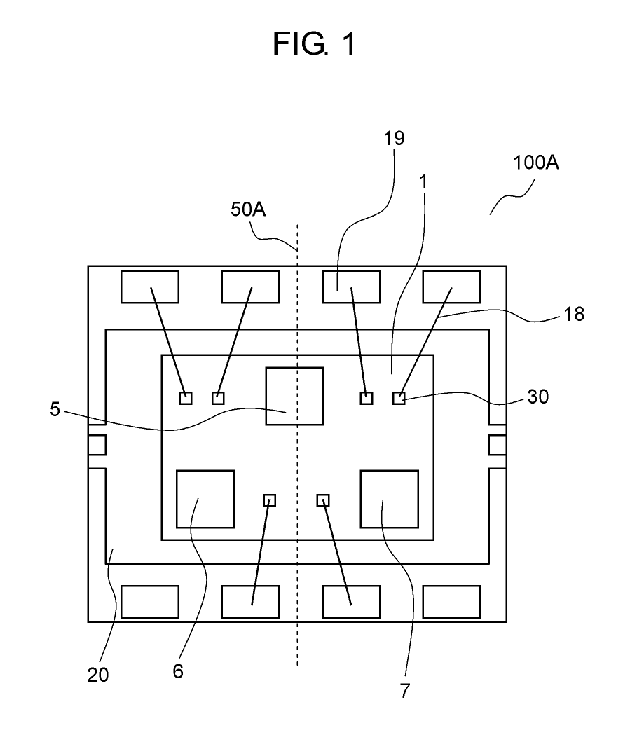

Magnetic sensor 100A according to a first exemplary embodiment of the present invention will now be described. First, the basic structure and sensing method of sensor 100A will now be described as follows. FIG. 1 is a schematic top view of sensor 100A.

Sensor 100A includes the pad 20, substrate 1, and a plurality of external terminals 19. Substrate 1 includes, on a first surface, a plurality of pads 30; a plurality of later-described magnetoresistive elements; and first magnet 5, second magnet 6, and third magnet 7 opposing the respective magnetoresistive elements. Pads 30 are electrically connected to the magnetoresistive elements. One of pads 30 is provided to read outputs from the magnetoresistive elements. Another of pads 30 is provided to apply a voltage to the magnetoresistive elements. Still another of pads 30 is provided to connect the magnetoresistive elements to the ground. First magnet 5 and second magnet 6 together form a magnet group, which preferably includes third magnet 7 as well. External terminals 19 are electrically connected to the respective pads 30 via wires 18.

Substrate 1 is preferably mounted on the pad 20 with the second surface down. Die pad 20 is made of metal and located on a ground pattern, so that the entire sensor 100A is protected from external noise.

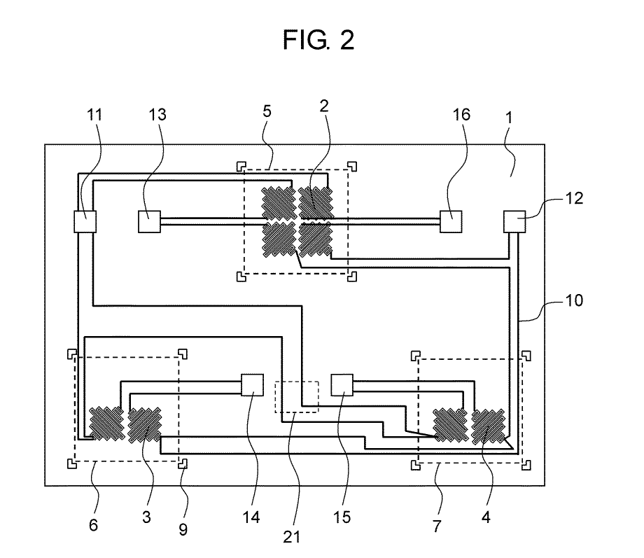

FIG. 2 is a schematic top view of substrate 1 with its first surface up. FIG. 2 mainly shows the magnetoresistive element patterns, wiring patterns, pads, etc. provided on substrate 1, and each region with a magnet is defined by a dotted line.

Substrate 1, the magnetoresistive elements located on substrate 1, and the magnets opposing the respective magnetoresistive elements together form the basic structure of sensor 100A. In short, sensor 100A includes substrate 1, the magnetoresistive element group, and the magnet group. Substrate 1 has the first surface and the second surface opposite to the first surface. The magnetoresistive element group includes first magnetoresistive element 2 and second magnetoresistive element 3, which are located on the first surface of substrate 1. The magnet group includes first magnet 5 opposing first magnetoresistive element 2, and second magnet 6 opposing second magnetoresistive element 3.

With this structure, magnetoresistive elements 2 and 3 of the magnetoresistive element group can be subjected to a magnetic bias applied by magnets 5 and 6, respectively. Thus, magnetoresistive elements 2 and 3 can be subjected to magnetic biases not only in the same direction but also in different directions, thereby increasing the design freedom. This achieves a highly compact, highly accurate magnetic sensor.

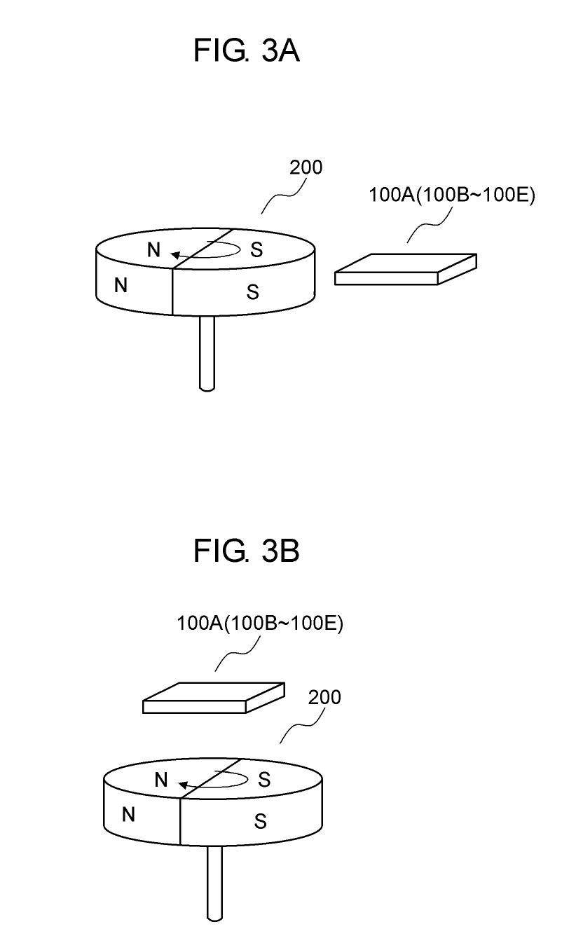

How magnetic sensor 100A senses magnet-to-be-detected 200 will now be described with reference to FIGS. 3A and 3B. Sensor 100A is located beside magnet-to-be-detected 200 in FIG. 3A, and is located over magnet-to-be-detected 200 in FIG. 3B. In FIGS. 3A and 3B, magnet-to-be-detected 200 is rotatable, but may be otherwise configured. For example, it can be a linear plate on which the north poles and the south poles are arranged alternately.

First, magnetic sensor 100A is placed to move relatively to the N-to-S (or S-to-N) direction of magnet-to-be-detected 200. More specifically, sensor 100A and magnet-to-be-detected 200 are located as shown in FIGS. 3A and 3B. In these arrangements, when magnet-to-be-detected 200 rotates and passes under or beside sensor 100A, its magnetic pole changes from north to south and vice versa alternately. This magnetic sensor can be a sensor having, for example, the property of changing its resistance depending on the magnetic field strength in a specific direction. Therefore, sensor 100A can read a change in magnetoresistance corresponding to a change from the north pole to the south pole or vice versa, thereby detecting the rotation angle of an object to be detected including magnet-to-be-detected 200.

More specifically, assume that the bias magnetic field applied by first magnet 5 to first magnetoresistive element 2 and the bias magnetic field applied by second magnet 6 to second magnetoresistive element 3 are separated in direction by 90 degrees. In that case, the magnetic fields applied from magnet-to-be-detected 200 to magnetoresistive elements 2 and 3 are separated in direction by 90 degrees between magnets 5 and 6. As a result, first and second magnetoresistive elements 2 and 3 have output characteristics of a sine wave (sin θ) and a cosine wave (cos θ), respectively, corresponding to a change from N pole to S pole and a change from S pole to N pole, respectively, of magnet-to-be-detected 200. The output characteristics indicate resistance change characteristics in a plot with time on the horizontal axis and resistance change on the vertical axis.

Next, tan θ, which indicates a rotation angle θ, is calculated from the sine and cosine waves. Thus, the rotation angle of the object to be detected can be detected.

The following is a specific description of how sensor 100A with the above-described structure detects magnet-to-be-detected 200. First, assume that a first output V₁ and a forth output V₄, both of which indicate the resistance change characteristics of first magnetoresistive element 2, can be expressed by the formula below.

V₁=V₄=sin θ

In this case, if second magnet 6 is separated from first magnet 5 by 90 degrees in the bias magnetic field direction, a second output V2, which indicates the resistance change characteristics of second magnetoresistive element 3, can be expressed by the formula below.

V₂=sin(θ+90°)=cos θ

In this case, if third magnet 7 is separated from second magnet 6 by 180 degrees (or from the first magnet by −90 degrees) in the bias magnetic field direction), a third output V3, which indicates the resistance change characteristics of third magnetoresistive element 4, can be expressed by the formula below.

V₃=sin(θ−90°)=−cos θ

The difference V₁₂ between the outputs V₁ and V₂ can be expressed by the formula below.

V₁₂=V₁−V₂=sin θ−cos θ=√2 sin(θ−45°)

The difference V₃₄ between the outputs V₃ and V₄ can be expressed by the formula below.

V₃₄=V₄−V₃=sin θ−(−cos θ)=√2 sin(θ+45°)

As a result, V₃₄ is separated by 90 degrees in phase from V₁₂. Therefore, if V₁₂ is a sine wave, then V₃₄ is a cosine wave. Next, tan θ, which indicates the rotation angle θ, is calculated from the sine and cosine waves. Thus, the rotation angle of the object to be detected can be detected.

It is preferable, as shown in FIGS. 1 and 2, that the magnetoresistive element group should include third magnetoresistive element 4, whereas the magnet group should include third magnet 7 opposing third magnetoresistive element 4. It is also preferable that when viewed two dimensionally, second and third magnetoresistive elements 3 and 4 should be line-symmetrical with respect to first axis 50A, and that first magnetoresistive element 2 should be on the first axis.

Furthermore, first magnetoresistive element 2 is preferably connected to voltage application pad 11, grounding pad 12, first output terminal 13, and fourth output terminal 16. Similarly, second magnetoresistive element 3 is preferably connected to voltage application pad 11, grounding pad 12, and second output terminal 14, whereas third magnetoresistive element 4 is preferably connected to voltage application pad 11, grounding pad 12, and third output terminal 15.

Third magnetoresistive element 4 and grounding pad 12 are indirectly connected via either first magnetoresistive element 2 or second magnetoresistive element 3. This preferred arrangement allows sensor 100A to have a reliable sensing function as will be described later.

The following are a description of the planar and cross-sectional structures of the magnetoresistive elements in sensor 100A and a description of the bias magnetic field direction of each magnet of the magnet group.

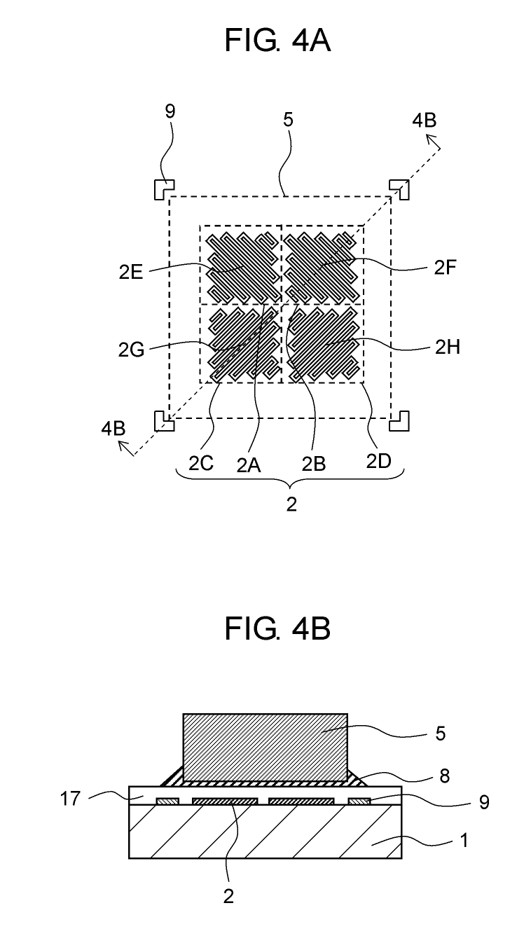

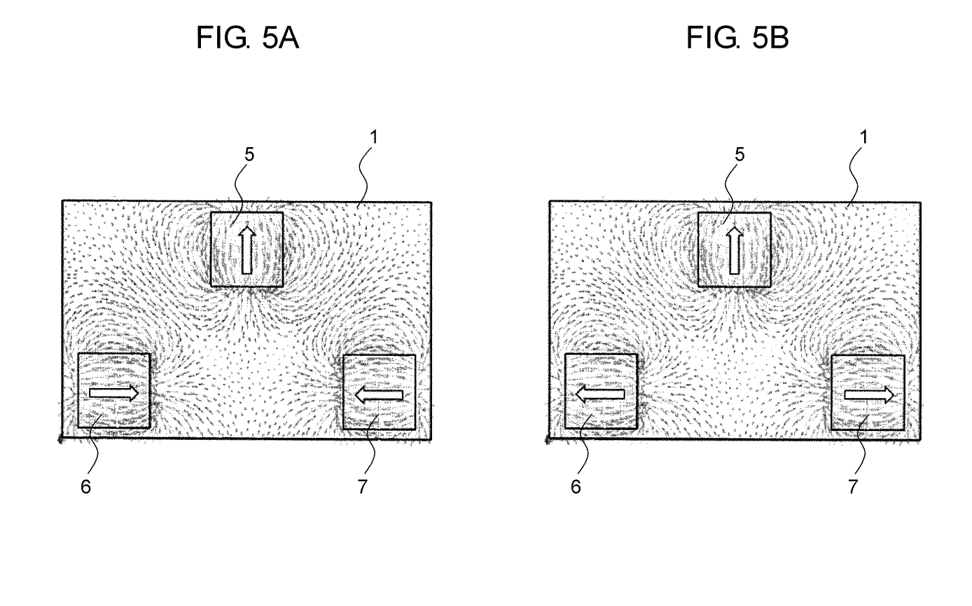

FIG. 4A is an enlarged view of first magnetoresistive element 2, and FIG. 4B is a sectional view taken along line 4B-4B of FIG. 4A. FIG. 5A shows a first example of the bias magnetic field direction of each magnet of the magnet group, and FIG. 5B shows a second example of the bias magnetic field direction of magnets 5-7 composing the magnet group. The arrows shown in magnets 5, 6, and 7 indicate the magnetic field directions (bias magnetic field directions). In other words, the magnetic poles of magnets 5-7 are located on respective sides thereof facing each other.

As shown in FIG. 4A, first magnetoresistive element 2 includes meandering patterns 2A, 2B, 2C, and 2D each having a plurality of bent parts. Patterns 2A, 2B, 2C, and 2D have linear parts 2E, 2F, 2G, and 2H, respectively, each of which is the largest linear part in each pattern. Linear parts 2E and 2H are separated by 90 degrees, linear parts 2F and 2G are separated by 90 degrees, and linear parts 2G and 2E are separated by 90 degrees. As known from FIGS. 4A, 5A, and 5B, linear parts 2E, 2F, 2G, and 2H are inclined 45 degrees with respect to the bias magnetic field direction of first magnet 5.

The relationship between the patterns of magnetoresistive elements 3, 4 and magnets 6, 7 opposing magnetoresistive elements 3, 4, respectively, is similar to the relationship between the pattern of first magnetoresistive element 2 and first magnet 5 opposing first magnetoresistive element 2. This arrangement allows sensor 100A to have a reliable sensing function.

It is preferable that the first surface of substrate 1 should be provided with positioning parts 9 at the corners of each of magnets 5-7 as shown in FIG. 4A for the following reason. In the case that positioning parts 9 are absent, if, for example, first magnet 5 is displaced, then the bias magnetic field direction of first magnet 5 may also be displaced, possibly damaging the reliability. In the case that positioning parts 9 are present, on the other hand, first magnet 5 can be repositioned by aligning its corners with positioning parts 9 under an optical microscope. Thus, first magnet 5 is prevented from being displaced, thereby improving the reliability.

Positioning parts 9 are preferably made of metal and also made of the same material as wires 10 extending from the magnetoresistive element group. Under these conditions, positioning parts 9 can be formed in the same process as wires 10, thereby reducing the cost. These conditions for first magnet 5 hold true for magnets 6 and 7.

It is preferable that as shown FIG. 4B, first magnet 5 should be located on first magnetoresistive element 2 via adhesive part 8 made of either thermosetting adhesive or UV-curable adhesive. Adhesive part 8 preferably covers part of a side surface of first magnet 5. In the case that adhesive part 8 is absent, if first magnet 5 is displaced, then the bias magnetic field direction of first magnet 5 may also be displaced, possibly damaging the reliability. In the case that adhesive part 8 is used, the thermosetting or UV-curable adhesive is cured after first magnet 5 is properly located, so that first magnet 5 can be prevented from being displaced, thereby improving reliability. These conditions for first magnet 5 hold true for magnets 6 and 7. It is alternatively possible to fix two or all of magnets 5-7 to the respective ones of magnetoresistive elements 2-4 via one adhesive part 8.

It is preferable that as shown in FIG. 4B, protective layer 17 containing a silicon oxide film or a fluorine-based resin film should be provided on the magnetoresistive element group. Adhesive part 8 could be directly located on the magnetoresistive element group, but the presence of protective layer 17 can improve the reliability of the product.

Each of magnetoresistive elements 2, 3, and 4 composing the magnetoresistive element group is preferably an artificial lattice film having a laminated structure of a magnetic layer containing Ni, Co, and Fe, and a non-magnetic layer containing Cu. In addition, magnetoresistive elements 2, 3, and 4 are preferably anisotropic magnetoresistive elements whose resistances change depending on the magnetic field strength in a specific direction.

Furthermore, although not shown, the magnetoresistive element group can be located on substrate 1 via an underlying film such as a silicon oxide film.

It is also preferable that as shown in FIGS. 5A and 5B, the magnetic field direction passing through the center of third magnet 7 should be parallel to the magnetic field direction passing through the center of second magnet 6, whereas the magnetic field direction passing through the center of second magnet 6 should be perpendicular to the magnetic field direction passing through the center of first magnet 5.

First, second, and third magnets 5, 6, and 7 are preferably located distant enough from each other to avoid interference among their magnetic fields, so that the rotation angle of the object to be detected can be detected with high accuracy.

As shown in FIG. 5A, the magnetic field direction passing through the center of third magnet 7 may be opposite to the magnetic field direction passing through the center of second magnet 6. Alternatively, as shown in FIG. 5B, the magnetic field passing through the center of each of third magnet 7 and second magnet 6 may be outward. The magnetic fields shown in FIG. 5A can be achieved by magnetizing each magnet separately, whereas the magnetic fields shown in FIG. 5B can be achieved by magnetizing all the magnets together.

It is preferable to provide processing circuit 21, which processes signals from the magnetoresistive element group, between second magnetoresistive element 3 and third magnetoresistive element 4 on the first surface of substrate 1 as shown in FIG. 2. Processing circuit 21 can amplify signals from the magnetoresistive element group. Circuit 21 can be located in a free space between second and third magnetoresistive elements 3 and 4 so as to contribute to minimizing the entire size of sensor 100A.

First magnet 5, second magnet 6, and third magnet 7 preferably contain resin and rare-earth magnetic powder dispersed in the resin. The resin preferably contains thermosetting resin, and the rare-earth magnetic powder is preferably SmFeN magnetic powder. SmFeN is advantageous in the manufacturing process because it has the property of allowing resin to be easily molded.

It is preferable that as shown in FIG. 2, second and third magnetoresistive elements 3 and 4 should be smaller in size than first magnetoresistive element 2. More specifically, first magnetoresistive element 2 preferably has four meandering patterns whereas second and third magnetoresistive elements 3 and 4 each have two meandering patterns. Alternatively, second and third magnetoresistive elements 3 and 4 may have dummy patterns so as to have the same number of meandering patterns as first magnetoresistive element 2.

### Second Exemplary Embodiment

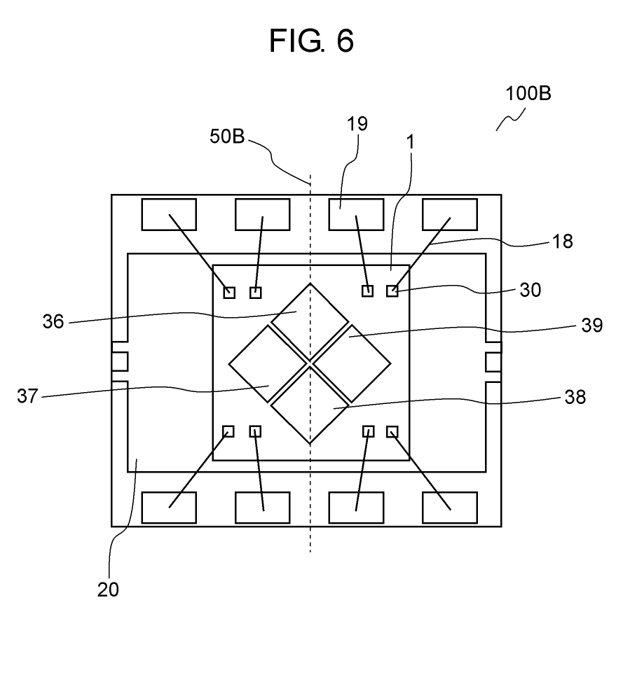

Magnetic sensor 100B according to a second exemplary embodiment of the present invention will now be described with reference to FIGS. 6-10. First, the basic structure and sensing method of sensor 100B will now be described as follows. FIG. 6 is a schematic top view of sensor 100B.

Similar to sensor 100A according to the first exemplary embodiment, sensor 100B includes the pad 20, substrate 1, and a plurality of external terminals 19. Substrate 1 includes, on a first surface, a plurality of pads 30; a plurality of later-described magnetoresistive elements; and first magnet 36, second magnet 37, third magnet 38, and fourth magnet 39 opposing the respective magnetoresistive elements. Pads 30 and the connection between external terminals 19 and pads 30 via wires 18 are the same as in the first exemplary embodiment, and the description thereof will be omitted.

First magnet 36 and second magnet 37 together form a magnet group, which preferably includes third magnet 38 and fourth magnet 39 as well.

Substrate 1 is preferably mounted on die pad 20 with the second surface down, as described in the first exemplary embodiment.

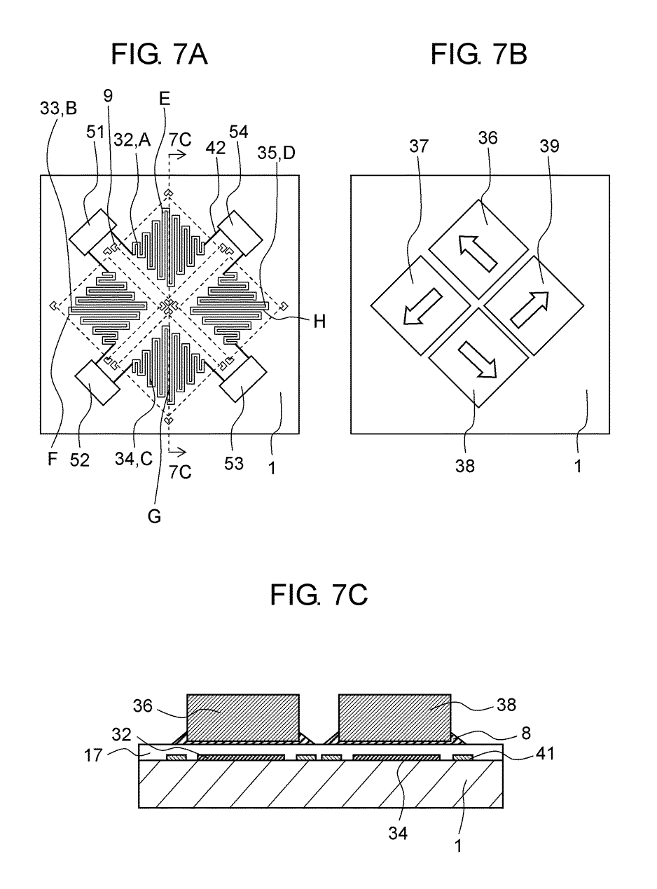

FIG. 7A is a schematic top view of substrate 1 with its first surface up. FIG. 7A mainly shows the magnetoresistive element patterns, wiring patterns, output terminals, etc. provided on substrate 1, and each region with a magnet is defined by a dotted line. FIG. 7B shows the spatial relationship between the magnet group and substrate 1 in sensor 100B. The arrows shown in FIG. 7B indicate the directions of the applied magnetic fields. FIG. 7C is a sectional view taken along line 7C-7C of FIG. 7A.

Substrate 1, the magnetoresistive elements located on substrate 1, and the magnets opposing the respective magnetoresistive elements together form the basic structure of sensor 100B. In short as shown in FIGS. 7A and 7C, sensor 100B includes substrate 1, the magnetoresistive element group, and the magnet group. Substrate 1 has the first surface and the second surface opposite to the first surface. The magnetoresistive element group includes first magnetoresistive element 32 and second magnetoresistive element 33, which are located on the first surface of substrate 1. The magnet group includes first magnet 36 opposing first magnetoresistive element 32, and second magnet 37 opposing second magnetoresistive element 33.

In sensor 100B, too, magnetoresistive elements 32 and 33 of the magnetoresistive element group can be subjected to a magnetic bias applied by magnets 36 and 37, respectively. Thus, magnetoresistive elements 32 and 33 can be subjected to magnetic biases not only in the same direction, but also in different directions, thereby increasing the design freedom. This achieves a highly compact, highly accurate magnetic sensor.

In the first exemplary embodiment, how sensor 100A senses magnet-to-be-detected 200 has been described with reference to FIGS. 3A and 3B. Sensor 100B senses magnet-to-be-detected 200 in the same manner as sensor 100A. In other words, first and second magnetoresistive elements 2, 3 and first and second magnets 5, 6 can be replaced by first and second magnetoresistive elements 32, 33 and first and second magnets 36, 37, respectively.

It is preferable that as shown in FIGS. 6, 7A, and 7B, the magnetoresistive element group should further include third magnetoresistive element 34 and fourth magnetoresistive element 35, whereas the magnet group should further include third magnet 38 opposing third magnetoresistive element 34 and fourth magnet 39 opposing fourth magnetoresistive element 35. In that case, as shown in FIG. 7B, the magnetic field direction passing through the center of first magnet 36 and the magnetic field direction passing through the center of third magnet 38 are parallel to each other, and the magnetic field direction passing through the center of second magnet 37 and the magnetic field direction passing through the center of fourth magnet 39 are parallel to each other. Furthermore, the magnetic field direction passing through the center of first magnet 36 and the magnetic field direction passing through the center of second magnet 37 are perpendicular to each other.

It is preferable that when viewed two dimensionally, second and fourth magnetoresistive elements 33 and 35 should be line-symmetrical with respect to first axis 50B, whereas first magnetoresistive element 32 should be on the first axis 50B. In other words, it is preferable that second and fourth magnets 37 and 39 should be line-symmetrical with respect to first axis 50B, whereas first and third magnets 36 and 38 should be on first axis 50B.

It is possible to arrange first and third magnetoresistive elements 32 and 34 line-symmetrically with respect to first axis 50B when viewed two dimensionally. In that case, second and fourth magnetoresistive elements 33 and 35 are preferably on first axis 50B. In other words, it is possible to arrange first and third magnets 36 and 38 line-symmetrically with respect to first axis 50B when viewed two dimensionally. In that case, second and fourth magnets 37 and 39 are on first axis 50B.

First magnetoresistive element 32 is preferably electrically connected to two pads 30: one for voltage application and the other for grounding, and also to first output terminal 51 and fourth output terminal 54 via wires 42. Second magnetoresistive element 33 is preferably connected to two pads 30: one for voltage application and the other for grounding, and also to first output terminal 51 and second output terminal 52. Third magnetoresistive element 34 is preferably connected to two pads 30: one for voltage application and the other for grounding, and also to second output terminal 52 and third output terminal 53. Fourth magnetoresistive element 35 is preferably connected to two pads 30: one for voltage application and the other for grounding, and also to third output terminal 53 and fourth output terminal 54. This preferred arrangement allows magnetic sensor 100B to have a reliable sensing function as will be described later.

It is further preferable that as shown in FIG. 7A, the distance between first and second magnetoresistive elements 32 and 33 should be equal to the distance between third and fourth magnetoresistive elements 34 and 35. It is also preferable that the distance between first and third magnetoresistive element 32 and 34 should be equal to the distance between second and fourth magnetoresistive elements 33 and 35. With these structures, the rotation angle θ can be detected with high accuracy. In the present application, the terms “equal” and “the same” mean substantially equal and substantially the same, respectively, within the allowable design errors.

The following are a description of the planar and cross-sectional structures of the magnetoresistive elements in sensor 100B, and a description of the bias magnetic field direction of each magnet of the magnet group, with reference to FIGS. 7A-7C.

As shown in FIG. 7A, first, second, third, and fourth magnetoresistive elements 32, 33, 34, and 35 include meandering patterns A, B, C, and D, respectively. Patterns A, B, C, and D have linear parts E, F, G, and H, respectively, each of which is the largest linear part in each pattern. Linear parts E and F are separated by 90 degrees, linear parts F and G are separated by 90 degrees, and linear parts G and H are separated by 90 degrees. As shown in FIGS. 7A and 7B, linear parts E, F, G, and H are inclined 45 degrees with respect to the bias magnetic field directions of first, second, third, and fourth magnets 36, 37, 38, and 39, respectively. This arrangement allows sensor 100B to have a reliable sensing function.

It is preferable that the first surface of substrate 1 should be provided with positioning parts 9 at the corners of each of magnets 36-39 as shown in FIG. 7A. Positioning parts 9 have the same structure and effects as in the first exemplary embodiment.

It is preferable that as shown in FIG. 7C, the magnet group should be located over the magnetoresistive element group. In this case, it is preferable that first magnet 36 should be located over first magnetoresistive element 32 via adhesive part 8 made of either thermosetting adhesive or UV-curable adhesive. Adhesive part 8 has the same structure and effects as in the first exemplary embodiment, and it is preferable that this structure of first magnet 36 should be applied to magnets 37, 38, and 39 as well.

It is preferable that as shown in FIG. 7C, protective layer 17 containing a silicon oxide film or a fluorine-based resin film should be provided on the magnetoresistive element group. Protective layer 17 has the same structure and effects as in the first exemplary embodiment. Also, each magnetoresistive element of the magnetoresistive element group has the same structure and effects as in the first exemplary embodiment.

Furthermore, although not shown, the magnetoresistive element group can be located on substrate 1 via an underlying film such as a silicon oxide film in the same manner as in the first exemplary embodiment.

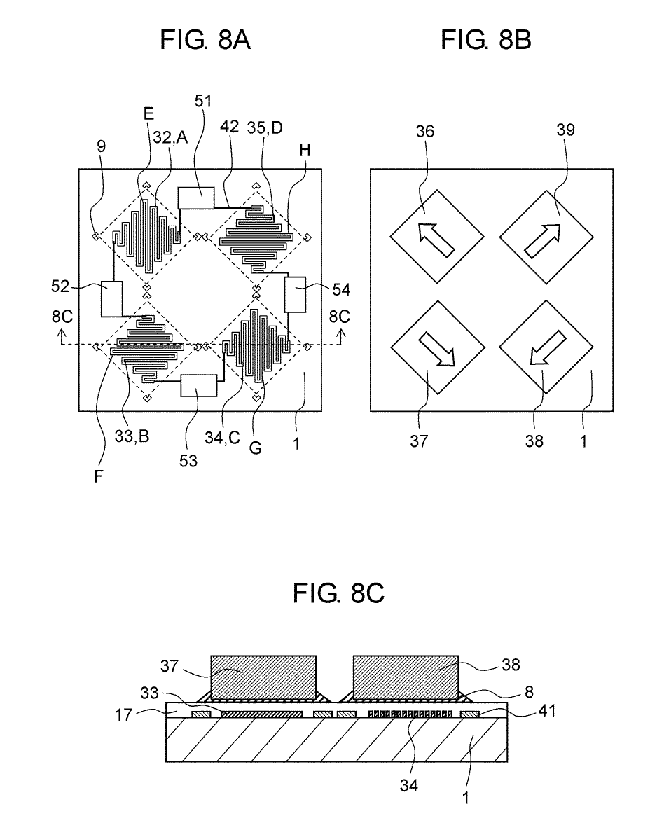

A first modified example of the arrangement between the magnet group and the magnetoresistive element group and of the bias magnetic field directions of the magnet group will now be described with reference to FIGS. 8A-8C. FIG. 8A is a schematic top view of substrate 1 including magnetoresistive elements 32-35 in the magnetic sensor according to the first modified example of the present exemplary embodiment. FIG. 8A mainly shows the magnetoresistive element patterns, wiring patterns, output terminals, etc. provided on substrate 1, and each region with a magnet is defined by a dotted line. FIG. 8B shows the spatial relationship between the magnet group and substrate 1 in the magnetic sensor. The arrows shown in FIG. 8B indicate the directions of the applied magnetic fields. FIG. 8C is a sectional view taken along line 8C-8C of FIG. 8A.

As shown in FIG. 8B, the magnetic field direction passing through the center of first magnet 36 is parallel to the magnetic field direction passing through the center of second magnet 37. The magnetic field direction passing through the center of third magnet 38 is perpendicular to the magnetic field direction passing through the center of first magnet 36. The magnetic field direction passing through the center of fourth magnet 39 is parallel to the magnetic field direction passing through the center of third magnet 38. More specifically, the magnetic field direction passing through the center of first magnet 36 is opposite to the magnetic field direction passing through the center of second magnet 37, whereas the magnetic field direction passing through the center of fourth magnet 39 is opposite to the magnetic field direction passing through the center of third magnet 38.

First, second, third, and fourth magnets 36, 37, 38, and 39 are preferably located distant enough from each other to avoid interference among their magnetic fields, so that the rotation angle of the object to be detected can be detected with high accuracy. In the present application, the terms “parallel” and “perpendicular” mean substantially parallel and substantially perpendicular, respectively, within the allowable design errors.

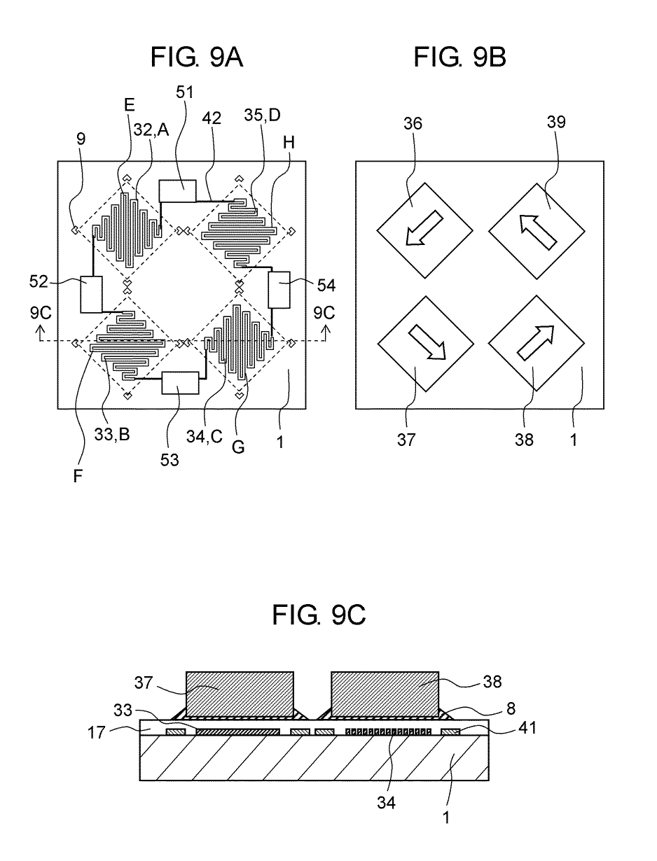

A second modified example of the arrangement between the magnet group and the magnetoresistive element group and of the bias magnetic field directions of the magnet group will now be described with reference to FIGS. 9A-9C. FIG. 9A is a schematic top view of substrate 1 including magnetoresistive elements 32-35 in the magnetic sensor according to the second modified example of the present exemplary embodiment. FIG. 9A mainly shows the magnetoresistive element patterns, wiring patterns, output terminals, etc. provided on the substrate, and each region with a magnet is defined by a dotted line. FIG. 9B shows the spatial relationship between the magnet group and the substrate in the magnetic sensor. The arrows shown in FIG. 9B indicate the directions of the applied magnetic fields. FIG. 9C is a sectional view taken along line 9C-9C of FIG. 9A.

As shown in FIG. 9B, the magnetic field direction passing through the center of first magnet 36 is parallel to the magnetic field direction passing through the center of third magnet 38. The magnetic field direction passing through the center of second magnet 37 is perpendicular to the magnetic field direction passing through the center of first magnet 36. The magnetic field direction passing through the center of fourth magnet 39 is parallel to the magnetic field direction passing through the center of second magnet 37. More specifically, the magnetic field direction passing through the center of first magnet 36 is opposite to the magnetic field direction passing through the center of third magnet 38, whereas the magnetic field direction passing through the center of fourth magnet 39 is opposite to the magnetic field direction passing through the center of second magnet 37.

First, second, third, and fourth magnets 36, 37, 38, and 39 are preferably located distant enough from each other to avoid interference among their magnetic fields, so that the rotation angle of the object to be detected can be detected with high accuracy in the same manner as in the first modified example.

Although not shown, it is preferable to provide a processing circuit, which processes signals from the magnetoresistive element group, on the first surface of substrate 1 in the same manner as in the first exemplary embodiment. In the first and second modified examples, it is preferable that the processing circuit should be surrounded by either the magnetoresistive element group or the magnet group. The processing circuit can amplify signals from the magnetoresistive element group. This circuit can be located, for example, in a free space between any pair of magnetoresistive elements 32, 33, 34, and 35 so as to contribute to minimizing the entire size of the magnetic sensor. The circuit can alternatively be located in a free space surrounded by either the magnetoresistive element group or the magnet group so as to contribute to minimizing the entire size of sensor 100B.

Preferred materials of magnets 36-39 and their effects are similar to those described in the first exemplary embodiment.

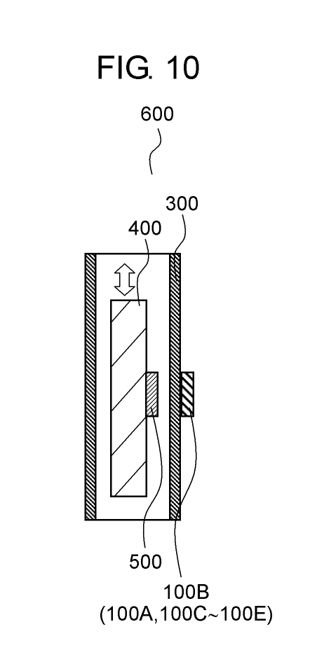

As shown in FIG. 10, magnetic sensor 100B is preferably located in structure 600. FIG. 10 is a schematic sectional view of structure 600 including sensor 100B.

More specifically, structure 600 includes cylindrical first member 300 including sensor 100B on its outer surface, and second member 400 located inside first member 300 and movable in the drawing direction of first member 300. Structure 600 further includes fifth magnet 500 on second member 400. Fifth magnet 500 is located aligned with sensor 100B in a direction perpendicular to the planar direction of sensor 100B. When second member 400 located as described above is moved in the drawing direction of first member 300 (in the direction of the arrow shown in FIG. 10), the spatial relationship between sensor 100B and fifth magnet 500 changes. As the spatial relationship changes, the magnetic field applied to each magnetoresistive element changes. Therefore, each magnetoresistive element reads the change in the magnetic field, thereby detecting the position of fifth magnet 500, or in other words, detecting the movement of second member 400 relative to first member 300. First member 300 may have various cross sections such as circular or square depending on the use.

Magnetic sensor 100B can be replaced by magnetic sensor 100A of the first exemplary embodiment, or any of magnetic sensors 100C-100E, which will be described in the third exemplary embodiment.

### Third Exemplary Embodiment

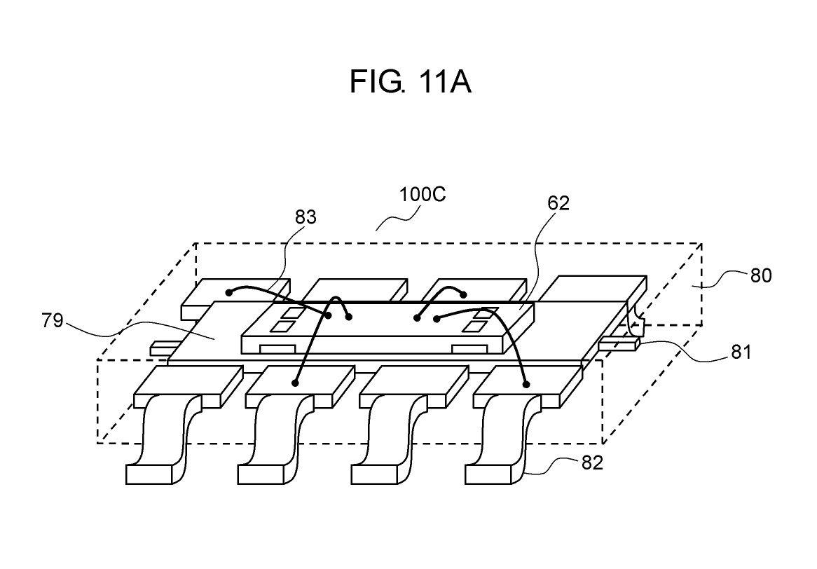

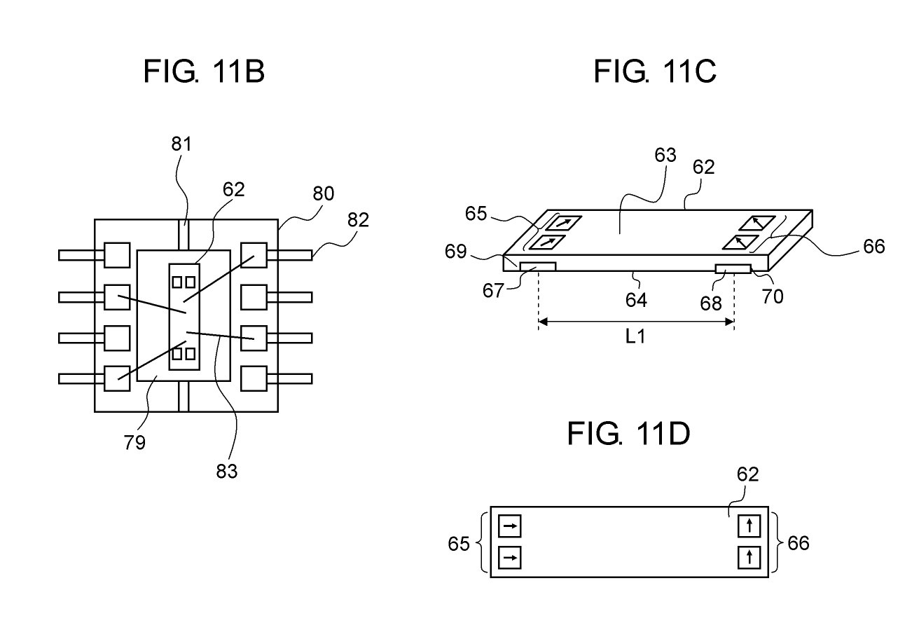

FIGS. 11A-11C are schematic diagrams of magnetic sensor 100C according to the third exemplary embodiment of the present invention. FIG. 11A is a perspective view of sensor 100C, and FIG. 11B is a top view of FIG. 11A. FIG. 11C is a perspective view of first substrate 62 in sensor 100C. In FIG. 11C, the arrows shown in first magnetoresistive element 65 and second magnetoresistive element 66, both of which are on first substrate 62, indicate the magnetization directions of first magnetic medium 67 and second magnetic medium 68, respectively.

As shown in FIGS. 11A and 11C, magnetic sensor 100C includes first substrate 62, first magnetoresistive element 65, second magnetoresistive element 66, first magnetic medium 67, and second magnetic medium 68. First substrate 62 has first surface 63 and second surface 64 opposite to first surface 63. Magnetoresistive elements 65 and 66 are located on first surface 63 of first substrate 62, whereas magnetic media 67 and 68 are located on second surface 64 of first substrate 62.

Sensor 100C further includes die pad 79, package 80, supporting part 81, terminals 82, and wires 83. Die pad 79 is mounted with first substrate 62. Supporting part 81 projects from die pad 79. Terminals 82 are provided on a surface of package 80 that is parallel to the direction in which supporting part 81 is extended. Magnetoresistive elements 65 and 66 on first substrate 62 are electrically connected to terminals 82 via wires 83.

With this structure, magnetoresistive elements 65 and 66 can be subjected to a magnetic bias applied by magnetic media 67 and 68, respectively. Thus, magnetoresistive elements 65 and 66 can be subjected to magnetic biases not only in the same direction but also in different directions, thereby increasing the design freedom. This allows magnetic sensor 100C to be more compact, and more accurate than the conventional magnetic sensors.

As described above, magnetic media 67 and 68 can apply a magnetic bias to magnetoresistive elements 65 and 66, respectively. Thus, magnetic media 67 and 68 correspond to magnets 5 and 6, respectively, used in the first exemplary embodiment. In other words, sensor 100C includes first substrate 62, first magnetoresistive element 65, second magnetoresistive element 66, first magnetic medium 67, and second magnetic medium 68. Magnetoresistive elements 65 and 66 are located on first surface 63 of first substrate 62. First magnetic medium 67 corresponding to first magnet 5 is located on second surface 64 of first substrate 62 and opposes first magnetoresistive element 65 via first substrate 62. Similarly, second magnetic medium 68 corresponding to second magnet 6 is located on second surface 64 of first substrate 62 and opposes second magnetoresistive element 66 via first substrate 62.

It is preferable that as shown in FIGS. 11A and 11C, first magnetic medium 67 should be located right under first magnetoresistive element 65 whereas second magnetic medium 68 should be located right under second magnetoresistive element 66. With this structure, magnetic media 67 and 68 can more easily exert a magnetic bias effect on magnetoresistive elements 65 and 66, respectively.

It is preferable that first magnetic medium 67 should be in first groove 69 formed on second surface 64 of first substrate 62 and that second magnetic medium 68 should be in second groove 70 formed on second surface 64 of first substrate 62. Magnetic media 67 and 68 could be bonded to second surface 64 of first substrate 62, but are preferably embedded in grooves 69 and 70, respectively, for miniaturization and cost reduction.

It is preferable that as shown in FIGS. 11A and 11B, first substrate 62 should be mounted on the pad 79 and be resin-sealed.

It is also preferable that in FIG. 11C, first and second magnetic media 67 and 68 should be distant from each other by not less than 0.05 mm and not more than 3.0 mm. This distance is shown as distance L₁ in FIG. 11C.

It is also preferable that as shown in FIG. 11C, first magnetic medium 67 should be different in magnetization direction from second magnetic medium 68. More specifically, it is preferable that as shown in FIG. 11C, first magnetic medium 67 should be separated in magnetization direction by 90 degrees from second magnetic medium 68. The phrase “separated by 90 degrees” includes being separated by substantially 90 degrees within the allowable design errors. Also, it is preferable that as shown in FIG. 11C, the magnetization direction of first magnetic medium 67 should be separated by 45 degrees from the longitudinal direction (the longer side direction) of first substrate 62, and second magnetic medium 68 should be perpendicular (including “substantially perpendicular”) in magnetization direction to first magnetic medium 67. The phrases “separated by 45 degrees” includes being separated by substantially 45 degrees within the allowable design errors. Alternatively, as shown in FIG. 11D, the magnetization direction of first magnetic medium 67 may be parallel (including “substantially parallel”) to the longitudinal direction (the longer side direction) of first substrate 62, and second magnetic medium 68 may be perpendicular (including “substantially perpendicular”) in magnetization direction to first magnetic medium 67.

It is preferable that as shown in FIG. 11C, first magnetoresistive element 65 should have two series-connected magnetoresistive elements, whereas second magnetoresistive element 66 should have two series-connected magnetoresistive elements. Each of magnetoresistive elements 65 and 66 only needs to have two or more magnetoresistive elements.

As described in the first exemplary embodiment, it is preferable to provide a processing circuit, which processes signals from first substrate 62, on die pad 79. The processing circuit also has the ability to drive first and second magnetoresistive elements 65 and 66 located on first substrate 62.

This processing circuit preferably processes output signals from second substrate 74, which will be described later. This circuit further has the ability to drive third magnetoresistive element 75 and fourth magnetoresistive element 76, which are located on second substrate 74.

First and second magnetic media 67 and 68 each preferably have resin and rare-earth magnetic powder dispersed in the resin. It is further preferable that magnetic media 67 and 68 should contain sulfur and nitrogen, and be a hard magnetic material. More specifically, magnetic media 67 and 68 preferably contain SmFeN, and further preferably, the SmFeN is in powder form dispersed in resin. Magnetic media 67 and 68 also preferably contain molding resin. SmFeN, which has the property of allowing resin to be easily molded and stabilized, and hence, allowing media 67 and 68 to be easily embedded in grooves 69 and 70 of first substrate 62.

In the first exemplary embodiment, how magnetic sensor 100A senses magnet-to-be-detected 200 has been described with reference to FIGS. 3A and 3B. How magnetic sensor 100C senses magnet-to-be-detected 200 will now be described with referent to these drawings.

Assume that first and second magnetic media 67 and 68 on first substrate 62 are separated in magnetization direction by 90 degrees. In that case, first magnetoresistive elements 65 and second magnetoresistive element 66 have output characteristics of a sine wave and a cosine wave, respectively, as in the first exemplary embodiment. These output characteristics correspond to a change from N pole to S pole and a change from S pole to N pole, respectively, of magnet-to-be-detected 200, and indicate resistance change characteristics in a plot with time on the horizontal axis and resistance change on the vertical axis. Next, tan θ, which indicates a rotation angle θ, is calculated from the sine and cosine waves.

Magnetoresistive elements 65 and 66 are preferably, for example, magneto resistive (MR) elements or giant magneto resistive (GMR) elements. Although elements 65 and 66 can be Hall elements, MR elements and GMR elements are advantageous because they can obtain twice the number of signals.

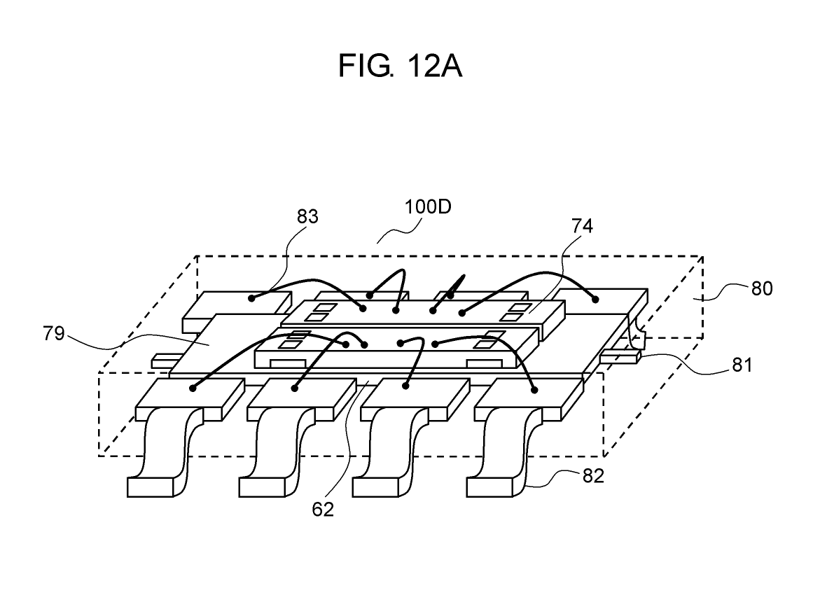

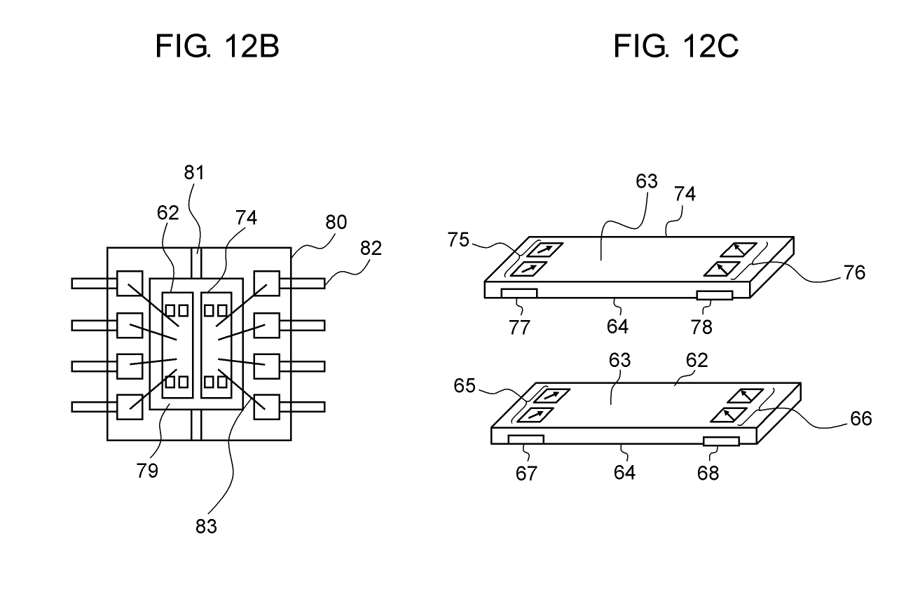

The following is a description of the first modified example of the present exemplary embodiment. FIGS. 12A-12C are schematic diagrams of magnetic sensor 100D according to the first modified example of the present exemplary embodiment. FIG. 12A is a perspective view of magnetic sensor 100D, and FIG. 12B is a top view of FIG. 12A. FIG. 12C is a perspective view of first substrate 62 and second substrate 74 in sensor 100D. The following description will be focused on differences from magnetic sensor 100C.

As shown in FIGS. 12A and 12C, sensor 100D includes not only first substrate 62 but also second substrate 74. More specifically, sensor 100D includes second substrate 74, third and fourth magnetoresistive elements 75 and 76, third magnetic medium 77, and fourth magnetic medium 78. Second substrate 74 has first surface 63 and second surface 64 opposite to first surface 63. Magnetoresistive elements 75 and 76 are located on first surface 63 of second substrate 74 whereas magnetic media 77 and 78 are located on second surface 64 of second substrate 74. As shown in FIGS. 12A and 12C, first surface 63 of first substrate 62 and first surface 63 of second substrate 74 are oriented in the same direction. First and second substrates 62 and 74 are preferably aligned in their lateral directions in terms of miniaturization.

In FIG. 12C, similar to FIG. 11C, the arrows shown in magnetoresistive elements 65 and 66 indicate the magnetization directions of magnetic media 67 and 68, respectively, and the arrows shown in magnetoresistive elements 75 and 76 indicate the magnetization directions of magnetic media 77 and 78, respectively.

Magnetoresistive elements 65, 66, 75, and 76 preferably have the same performance. First substrate 62 and second substrate 74 have preferably an equal area when viewed two dimensionally. With this structure, if any of magnetoresistive elements 65 and 66 in first substrate 62 is at fault, magnetoresistive elements 75 and 76 on second substrate 74 can perform backup functions.

It is preferable that as shown in FIGS. 12A and 12B, second substrate 74 should be mounted on the pad 79 whereas first substrate 62 and second substrate 74 should be parallel in their longitudinal direction (longer side direction). It is also preferable that first and second substrates 62 and 74 should be symmetrical with respect to the center of sensor 100D in order to stabilize the center of gravity of the entire package 80.

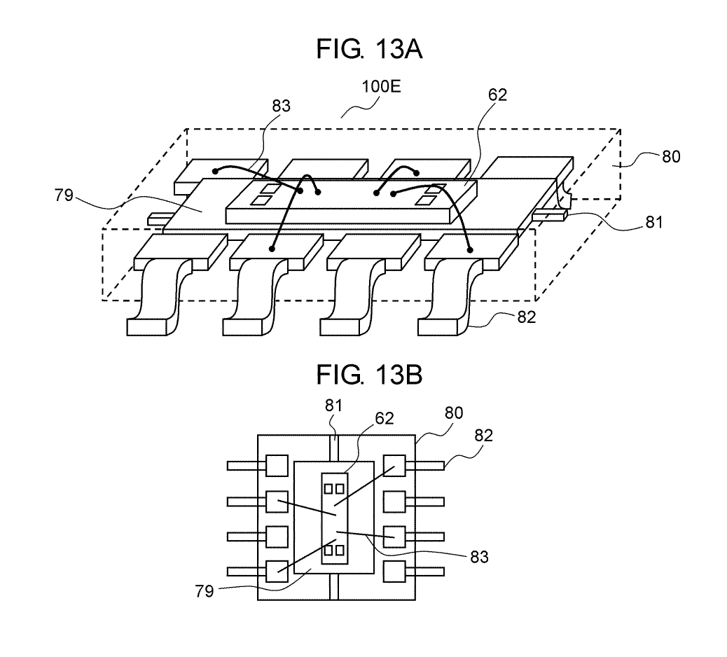

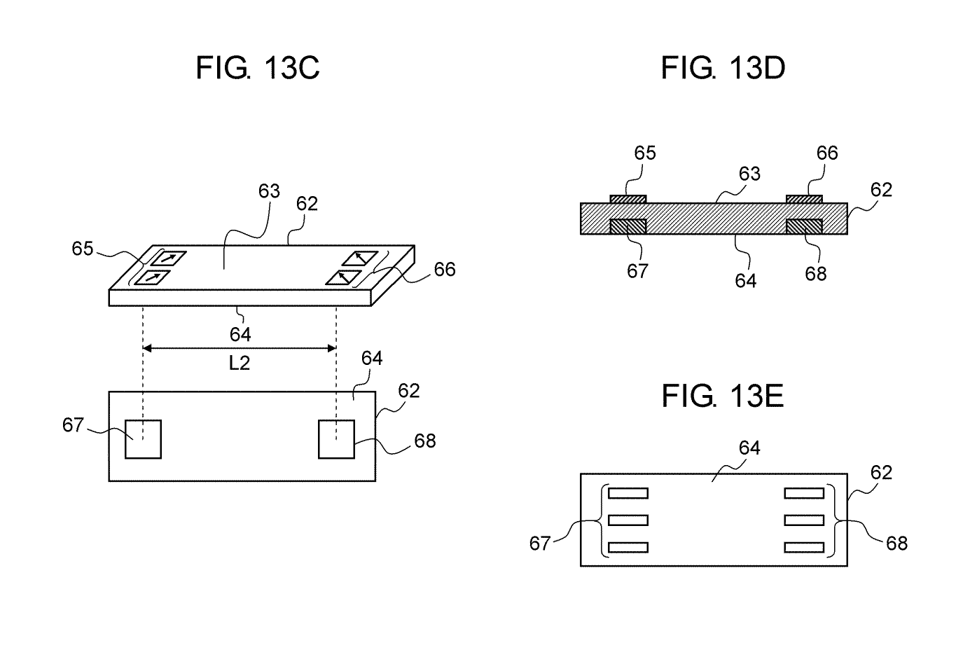

The second modified example of the present exemplary embodiment will now be described as follows. FIGS. 13A-13D are schematic diagrams of magnetic sensor 100E according to the second modified example of the present exemplary embodiment. FIG. 13A is a perspective view of sensor 100E and FIG. 13B is a top view of FIG. 13A. FIG. 13C is a perspective view and a rear view of first substrate 62 in sensor 100E. FIG. 13D is a sectional view of magnetoresistive elements 65 and 66 on first substrate 62.

Magnetic sensor 100E differs from magnetic sensor 100C in that as shown in FIGS. 13C and 13D, when viewed two dimensionally, first magnetic medium 67 is shorter in the longitudinal direction (the longer side direction) than first magnetoresistive element 65, and second magnetic medium 68 is shorter in the longitudinal direction (the longer side direction) than second magnetoresistive element 66. Also, the arrows shown in magnetoresistive elements 65 and 66 of FIG. 13C indicate the magnetization directions of magnetic media 67 and 68. Reducing the layout area of magnetic media 67 and 68 contributes to cost reduction. For example, as shown in FIGS. 13C and 13D, the longitudinal direction (the longer side direction) of magnetic media 67 and 68 can be reduced by providing grooves not throughout but only in part of the lateral direction of first substrate 62 when viewed two dimensionally.

As shown in FIG. 13E, it is possible to provide a plurality of first magnetic media 67 in the longitudinal direction (the longer side direction) of first magnetoresistive element 65. This structure increases the degree of layout freedom of the magnetic media.

It is preferable that first magnetoresistive element 65 should have series-connected magnetoresistive elements and that the number of the series-connected magnetoresistive elements should be greater than the number of first magnetic media 67. Thus, the magnetic media and the magnetoresistive elements can have a higher degree of layout freedom. For example, the structure shown in FIGS. 13C-13D includes two series-connected first magnetoresistive elements 65 and one first magnetic medium 67; however, the present exemplary embodiment is not the only option available. When there are three first magnetic media 67 as shown in FIG. 13E, it is preferable that there should be four or more series-connected first magnetoresistive elements 65. This holds true for the relationship between second magnetoresistive element 66 and second magnetic medium 68.

Only one magnetic medium 67 and only one magnetic medium 68 are provided in FIGS. 13C and 13D; alternatively, however, a plurality of magnetic media 67 and a plurality of magnetic media 68 may be provided in the length direction of magnetoresistive elements 65 and 66, respectively. In that case, the plurality of first magnetic media 67 located right under first magnetoresistive elements 65 preferably have the same magnetization direction. This holds true for second magnetic media 68 located right under second magnetoresistive element 66.

It is preferable for mass production to form magnetic media 67 and 68 as follows. Grooves formed on a silicon wafer are filled with rare-earth magnetic powder such as SmFeN and with fluid resin such as thermosetting resin (epoxy resin, silicone resin, urethane resin, etc.). Next, the magnetic powder and the resin are cured.

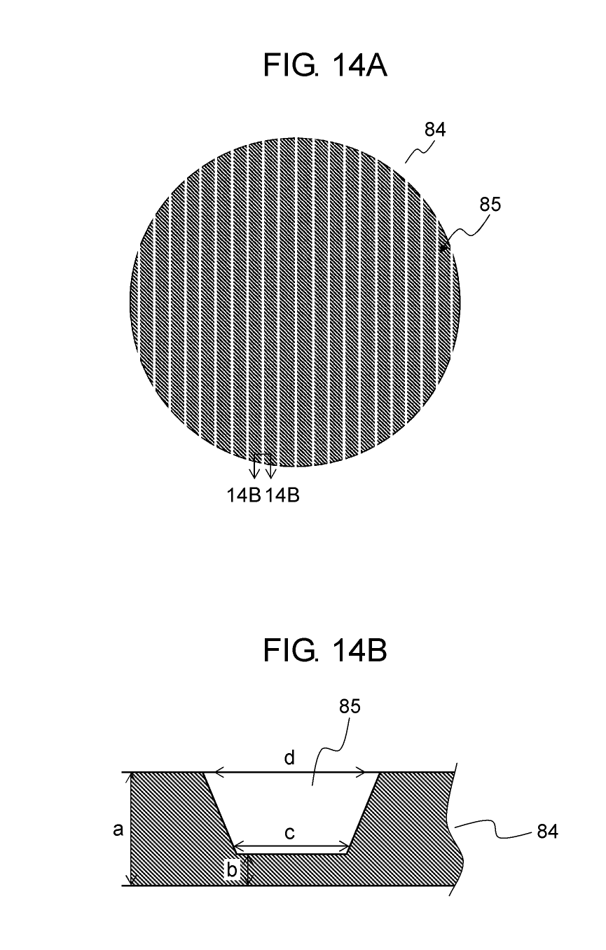

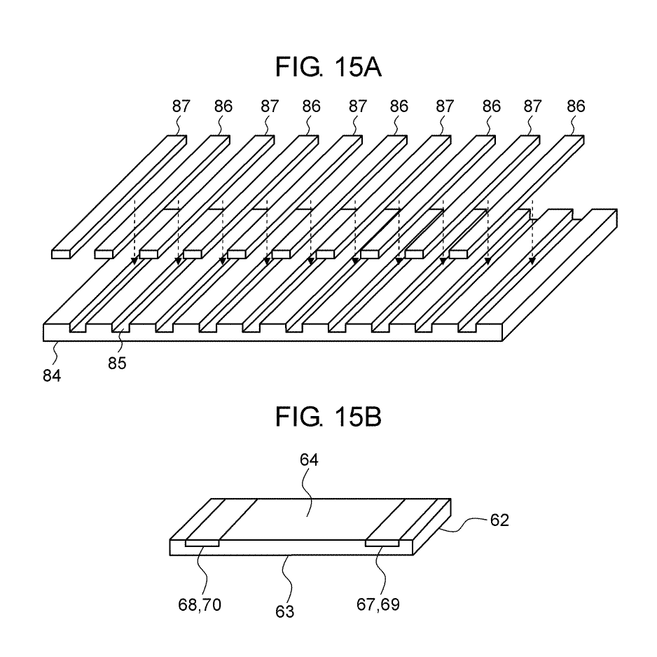

A method of forming first substrate 62 of each of magnetic sensors 100C and 100D will now be described with reference to FIGS. 14A-15B. FIGS. 14A-15B are drawings illustrating forming processes of first substrate 62. This forming method is also true for second substrate 74.

First, as shown in FIG. 14A, wafer 84 is prepared. First substrate 62 is preferably a silicon substrate, and therefore wafer 84 is preferably a silicon wafer.

Next, as shown in FIG. 14A, a plurality of substantially parallel arranged grooves 85 are formed on wafer 84 by wet etching. FIG. 14B is a sectional view taken along line 14B-14B of FIG. 14A. Grooves 85 are preferably about 0.65 mm in width and about 0.3 mm in depth. The pitch between the grooves is preferably about 2.0 mm. More specifically, it is preferable that as shown in FIG. 14B, a length “a” should be in the range of 0.5 mm to 5.0 mm, inclusive, a length “b” should be in the range of 0.5 mm to 3.0 mm, inclusive, a length “c” should be in the range of 0.2 mm to 4.0 mm, inclusive, and a length “d” should be in the range of 0.25 mm to 2.0 mm, inclusive. As shown in FIG. 14B, the length “c” is preferably shorter than the length “d”. In short, it is preferable that first groove 69 and second groove 70 formed on first substrate 62 should have a small-width portion from second surface 64 of first substrate 62 toward first surface 63.

Next, as shown in FIG. 15A, magnetic media 86 having a first magnetic orientation and magnetic media 87 having a second magnetic orientation are embedded alternately in grooves 85 of wafer 84.

Next, wafer 84 is diced to form first substrate 62 as shown in FIG. 15B having first magnetic medium 67, which is part of magnetic medium 86 and second magnetic medium 68, which is part of magnetic medium 87. Next, first and second magnetic media 67 and 68 are magnetized so as to form magnetic medium 67 along the first magnetic orientation and magnetic medium 68 along the second magnetic orientation.

### INDUSTRIAL APPLICABILITY

The present invention provides a highly compact, highly accurate magnetic sensor.

### REFERENCE MARKS IN THE DRAWINGS

1 substrate
2, 32, 65 first magnetoresistive element (magnetoresistive element)
A, B, C, D, 2A, 2B, 2C, 2D pattern
E, F, G, H, 2E, 2F, 2G, 2H linear part
3, 33, 66 second magnetoresistive element (magnetoresistive element)
4, 34, 75 third magnetoresistive element (magnetoresistive element)
5, 36 first magnet (magnet)
6, 37 second magnet (magnet)
7, 38 third magnet (magnet)
8 adhesive part
9 positioning part
10, 18, 42, 83 wire
11 voltage application pad
12 grounding pad
13, 51 first output terminal
14, 52 second output terminal
15, 53 third output terminal
16, 54 fourth output terminal
17 protective layer
19 external terminal
20, 79 die pad
21 processing circuit
30 pad
35, 76 fourth magnetoresistive element
39 fourth magnet (magnet)
50A, 50B first axis
62 first substrate
63 first surface
64 second surface
67 first magnetic medium (magnetic medium)
68 second magnetic medium (magnetic medium)
69 first groove (groove)
70 second groove (groove)
74 second substrate
77 third magnetic medium (magnetic medium)
78 fourth magnetic medium (magnetic medium)
80 package
81 supporting part
82 terminal
84 wafer
85 groove
86, 87 magnetic medium
100A, 100B, 100C, 100D, 100E magnetic sensor
200 magnet-to-be-detected
300 first member
400 second member
500 fifth magnet
600 structure

1. A magnetic sensor comprising:
a substrate having a first surface and a second surface opposite to the first surface;
a magnetoresistive element group including a first magnetoresistive element and a second magnetoresistive element located on the first surface of the substrate; and
a magnet group including:
a first magnet opposing the first magnetoresistive element; and
a second magnet opposing the second magnetoresistive element.

2. The magnetic sensor of claim 1, wherein
the magnetoresistive element group further includes a third magnetoresistive element, and
the magnet group further includes a third magnet opposing the third magnetoresistive element,
wherein when viewed two dimensionally, the second magnetoresistive element and the third magnetoresistive element are line-symmetrical with respect to a first axis, and the first magnetoresistive element is on the first axis.

3. The magnetic sensor of claim 2, wherein
a magnetic field direction passing through a center of the third magnet is parallel to a magnetic field direction passing through a center of the second magnet, and
the magnetic field direction passing through the center of the second magnet is perpendicular to a magnetic field direction passing through a center of the first magnet.

4. The magnetic sensor of claim 2, wherein the second magnetoresistive element and the third magnetoresistive element are smaller in size than the first magnetoresistive element.

5. The magnetic sensor of claim 2, further comprising a processing circuit located between the second magnetoresistive element and the third magnetoresistive element on the first surface of the substrate, the processing circuit processing a signal from the magnetoresistive element group.

6. The magnetic sensor of claim 1, wherein a magnetic field direction passing through a center of the first magnet is opposite to a magnetic field direction passing through a center of the second magnet.

7. The magnetic sensor of claim 1 further comprising at least one adhesive part made of either thermosetting adhesive or UV-curable adhesive and disposed either between the first magnet and the first magnetoresistive element or between the second magnet and the second magnetoresistive element.

8. The magnetic sensor of claim 7, wherein the at least one adhesive part covers part of a side surface of the first magnet.

9. The magnetic sensor of claim 1, wherein the first surface of the substrate is provided with a plurality of positioning parts corresponding to corners of each of the first magnet and the second magnet.

10. The magnetic sensor of claim 9, wherein the positioning parts are made of metal.

11. The magnetic sensor of claim 9, wherein the positioning parts are made of a same material as a wire extending from the magnetoresistive element group.

12. The magnetic sensor of claim 1, wherein a magnetic field direction passing through a center of the first magnet and a magnetic field direction passing through a center of the second magnet are either parallel or perpendicular to each other.

13. The magnetic sensor of claim 1, wherein
the magnetoresistive element group further includes a third magnetoresistive element and a fourth magnetoresistive element,
the magnet group further includes a third magnet opposing the third magnetoresistive element and a fourth magnet opposing the fourth magnetoresistive element,
a magnetic field direction passing through a center of the first magnet and a magnetic field direction passing through a center of the third magnet are parallel to each other,
a magnetic field direction passing through a center of the second magnet and a magnetic field direction passing through a center of the fourth magnet are parallel to each other, and
the magnetic field direction passing through the center of the first magnet and the magnetic field direction passing through the center of the second magnet are perpendicular to each other.

14. The magnetic sensor of claim 13, wherein
the second magnet and the fourth magnet are line-symmetrical with respect to a first axis, and
the first magnet and the third magnet are on the first axis.

15. The magnetic sensor of claim 13, wherein
the magnetic field direction passing through the center of the first magnet and the magnetic field direction passing through the center of the third magnet are opposite to each other, and
the magnetic field direction passing through the center of the second magnet and the magnetic field direction passing through the center of the fourth magnet are opposite to each other.

16. The magnetic sensor of claim 13, wherein a distance between the first magnetoresistive element and the second magnetoresistive element is identical to a distance between the third magnetoresistive element and the fourth magnetoresistive element.

17. The magnetic sensor of claim 13, wherein a distance between the first magnetoresistive element and the third magnetoresistive element is identical to a distance between the second magnetoresistive element and the fourth magnetoresistive element.

18. The magnetic sensor of claim 1, wherein the magnet group is located over the magnetoresistive element group.

19. The magnetic sensor of claim 1, wherein the first magnet and the second magnet are located on the second surface of the substrate.

20. The magnetic sensor of claim 1, wherein the first magnet and the second magnet each contain resin and rare-earth magnetic powder dispersed in the resin.

21. The magnetic sensor of claim 20, wherein the resin contains thermosetting resin, and the rare-earth magnetic powder is SmFeN magnetic powder.

22. The magnetic sensor of claim 1, further comprising a protective layer covering the magnetoresistive element group, the protective layer containing either a silicon oxide film or a fluorine-based resin film.

23. The magnetic sensor of claim 1, further comprising a die pad on which the substrate is mounted with the second surface down.
